(19) United States
(12) Patent Application Publication
(10) Pub. No.: US 2026/0191047 A1
(43) Pub. Date: Jul. 2, 2026

(54) ELECTRONIC DEVICE AND A METHOD FOR MANUFACTURING THE SAME

(71) Applicant: Innolux Corporation, Miaoli County (TW)

(72) Inventors: Ju-Li Wang, Miaoli County (TW); Po-Yun Hsu, Miaoli County (TW); Chin-Ming Huang, Miaoli County (TW); Ker-Yih Kao, Miaoli County (TW)

(73) Assignee: Innolux Corporation, Miaoli County (TW)

(21) Appl. No.: 19/399,680

(22) Filed: Nov. 25, 2025

Related U.S. Application Data
(60) Provisional application No. 63/739,685, filed on Dec. 30, 2024.

(30) Foreign Application Priority Data
Aug. 20, 2025 (CN) 202511170195.9

(51) Int. Cl. H10W 70/63; H10W 46/00; H10W 70/05; H10W 70/60; H10W 70/68; H10W 70/685; H10W 90/00; H10W 90/10; H10W 90/22

(52) U.S. Cl. CPC H10W 70/635; H10W 70/095; H10W 70/614; H10W 70/682; H10W 70/686; H10W 90/22; H10W 90/401; H10W 90/734; H10W 46/607; H10W 90/10

(57) ABSTRACT

Provided are an electronic device and a method for manufacturing the same. The electronic device includes a substrate including first and second surfaces opposite to each other in a first direction and including a cavity and a through hole penetrating the first and second surfaces, a first electronic unit disposed in the cavity, a conductive element disposed in the through hole and electrically connected to the first electronic unit and including a seed layer pattern and a conductive pillar extending from the seed layer pattern along the first direction, and a circuit structure disposed on the first surface of the substrate and electrically connected to the first electronic unit and the conductive element.

### CROSS-REFERENCE TO RELATED APPLICATION

This application claims the priority benefits of U.S. provisional application Ser. No. 63/739,685, filed on Dec. 30, 2024, and China application serial no. 202511170195.9, filed on Aug. 20, 2025. The entirety of each of the above-mentioned patent applications is hereby incorporated by reference herein and made a part of this specification.

### BACKGROUND

### Technical Field

The disclosure relates to an electronic device and a method for manufacturing the same, and particularly relates to an electronic device with good reliability and a method for manufacturing the same.

### Related Art

In current semiconductor packaging technology, mounting electronic units with different functions on the same substrate is one of the means to enhance the performance of electronic devices. However, as the performance requirements for electronic devices from users continue to increase, the density of electronic units is also increasing. Therefore, they need to be mounted on substrates with through holes, which makes the alignment margin of electronic units more stringent. Additionally, the aspect ratio of the through holes penetrating the substrate continues to increase, making it difficult for conductive elements formed in the through holes to meet current or future reliability requirements.

Accordingly, persons skilled in the art continue to improve the reliability of electronic devices.

### SUMMARY

The disclosure provides an electronic device and a method for manufacturing the same, which helps improve the reliability of the electronic device.

According to an embodiment of the disclosure, an electronic device includes a substrate, a first electronic unit, a conductive element, and a circuit structure. The substrate includes a first surface and a second surface opposite to each other in a first direction, in which the substrate includes a cavity and a through hole penetrating the first surface and the second surface; the first electronic unit is disposed in the cavity; the conductive element is disposed in the through hole and electrically connected to the first electronic unit, in which the conductive element includes a seed layer pattern and a conductive pillar extending from the seed layer pattern along the first direction; and the circuit structure is disposed on the first surface of the substrate and is electrically connected to the first electronic unit and the conductive element.

According to an embodiment of the disclosure, a method for manufacturing an electronic device includes the following steps. A substrate is provided, in which the substrate includes a first surface and a second surface opposite to each other in a first direction, and includes a cavity extending from the first surface into the substrate and a through hole penetrating the first surface and the second surface. A conductive element is provided in the through hole, in which the conductive element includes a seed layer pattern and a conductive pillar extending from the seed layer pattern along the first direction. A first electronic unit is provided in the cavity. Also, a circuit structure is provided on the first surface of the substrate, in which the circuit structure is electrically connected to the first electronic unit and the conductive element.

Based on the above, in the electronic device and the method for manufacturing the same according to embodiments of the disclosure, the conductive element includes a seed layer pattern and a conductive pillar extending from the seed layer pattern in a direction perpendicular to the first surface and the second surface of the substrate (that is, extending along the first direction). That is, the conductive element is provided in the through hole of the substrate by assembly method, thus may reduce negative effects caused by the process of forming the conductive pillar on the substrate or on the first electronic unit disposed in the substrate, thereby improving the reliability of the electronic device.

To make the foregoing features and advantages of the disclosure more comprehensible, embodiments are specifically provided below and described in detail with reference to the accompanying drawings.

### BRIEF DESCRIPTION OF THE DRAWINGS

The drawings are included to provide a further understanding of the disclosure, and the drawings are incorporated in and constitute a part of this specification. The drawings illustrate embodiments of the disclosure and, together with the description, serve to explain the principles of the disclosure.

FIG. 1 to FIG. 5 are schematic cross-sectional views of a method for manufacturing an electronic device according to an embodiment of the disclosure.

FIG. 6 is a schematic cross-sectional view of an electronic device according to another embodiment of the disclosure.

FIG. 7 is a schematic cross-sectional view of an electronic device according to yet another embodiment of the disclosure.

FIG. 8 is a block diagram of a method for manufacturing an electronic device according to an embodiment of the disclosure.

### DESCRIPTION OF THE EMBODIMENTS

The disclosure may be understood by reference to the following detailed description in conjunction with the accompanying drawings. It should be noted that, for ease of understanding by the reader and for simplicity of the drawings, multiple drawings in the disclosure show merely a part of the package structure, and specific elements in the drawings are not drawn to actual scale. In addition, the number and dimensions of elements in the drawings are merely for illustration and are not intended to limit the scope of the disclosure. For example, for clarity, the relative dimensions, thickness, and positions of various layers, regions, and/or structures may be reduced or enlarged.

Certain terms are used throughout this specification and the appended claims to refer to particular elements. Persons skilled in the art should understand that electronic equipment manufacturers may refer to the same element by different names. This document does not intend to distinguish between elements that have the same function but different names. In the following specification and appended claims, terms such as “having” and “including” are open-ended terms, and therefore should be interpreted to mean “including but not limited to . . . ”.

In this document, “one element is disposed on another element” is used for convenience to describe the relative position between the element and the another element, and is not intended to limit the process steps or sequence of the element and the another element.

The directional terms mentioned in this document, such as: “upper”, “lower”, “front”, “rear”, “left”, “right”, are merely references to the direction of the drawings. Therefore, the directional terms used are for illustration and are not intended to limit the disclosure. It should be understood that when an element or layer is referred to as being disposed “on” or “connected to” another element or layer, the element or layer may be directly on or directly connected to the another element or layer, or there may be intervening elements or layers therebetween (indirect case). Conversely, when an element or layer is referred to as being “directly” “on” or “directly connected to” another element or layer, there are no intervening elements or layers therebetween. Additionally, when an element or layer is referred to as overlapping another element, the element or layer at least partially overlaps the another element or layer.

The terms “about”, “approximately”, “substantially”, or “roughly” mentioned in this document typically represent falling within a 10% range of a given value or range, or represent falling within a 10%, 1%, or 0.5% range of a given value or range. Furthermore, the phrase “a given range is from a first value to a second value”, “a given range falls within the range from a first value to a second value” indicates that the given range includes the first value, the second value, and other values therebetween.

In some embodiments of the disclosure, terms regarding bonding and connecting such as “connect”, “interconnect”, unless specifically defined, may refer to two structures being in direct contact, or may also refer to two structures not being in direct contact, with other structures disposed between the two structures. Terms regarding bonding and connecting may also include cases where both structures are movable, or both structures are fixed. Furthermore, the terms “electrically connect” and “couple” include any direct and indirect electrical connection means.

In the following embodiments, the same or similar elements will adopt the same or similar reference numerals, and redundant description thereof will not be repeated. Furthermore, features in different embodiments may be arbitrarily mixed and matched for use as long as they do not violate the spirit of the disclosure or conflict with each other, and simple equivalent changes and modifications made according to this specification or appended claims are still within the range covered by the disclosure. That is, the following embodiments may substitute, recombine, and mix technical features from several different embodiments to complete other embodiments without departing from the spirit of the disclosure. Additionally, terms such as “first” and “second” mentioned in this specification or appended claims are merely used to name different elements or distinguish different embodiments or ranges, and are not used to limit the upper or lower limit of the number of elements, nor are they used to limit the manufacturing sequence or arrangement sequence of elements.

In some embodiments of the disclosure, the measurement method for thickness, length and width may be obtained by measurement using an optical microscope (OM), while thickness or width may be obtained by measurement from cross-sectional images in an electron microscope, but the disclosure is not limited thereto.

In some embodiments of the disclosure, surface roughness may be observed using electron microscopes such as a Scanning Electron Microscope (SEM), a Transmission Electron Microscope (TEM), by examining the condition of surface undulation under appropriate and consistent magnification, and the undulation conditions may be compared over a unit length (for example, 10 μm). In some embodiments, the peaks and valleys of surface undulation have a distance difference of 0.15 μm to 1 μm. Appropriate magnification means that at least one surface may see roughness or average roughness of at least 10 undulating peaks under the field of view of this magnification. Each film layer shown in the drawings of the disclosure may all be rough surfaces. It is worth noting that the rough surface of each film layer mentioned above may refer to the high and low undulation condition presented in cross-sectional views when observing the surface of each film layer through an electron microscope.

The process of the electronic device in the disclosure may be applied in wafer-level package (WLP) or panel-level package (PLP) process, and may be chip first or chip last. The electronic device described in the disclosure may be applied to high-speed computing modules, power modules, semiconductor packaging devices, display devices, light-emitting devices, backlight devices, antenna devices, silicon photonics co-packaging devices, sensing devices, or tiled devices, but the disclosure is not limited thereto.

The following are exemplary embodiments of the disclosure, where the same reference numerals are used in the drawings and description to represent the same or similar parts.

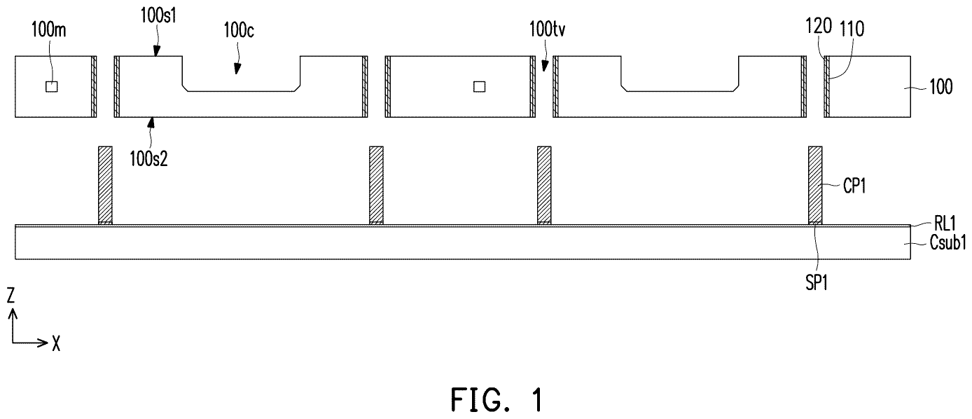

FIG. 1 to FIG. 5 are schematic cross-sectional views of a method for manufacturing an electronic device according to an embodiment of the disclosure.

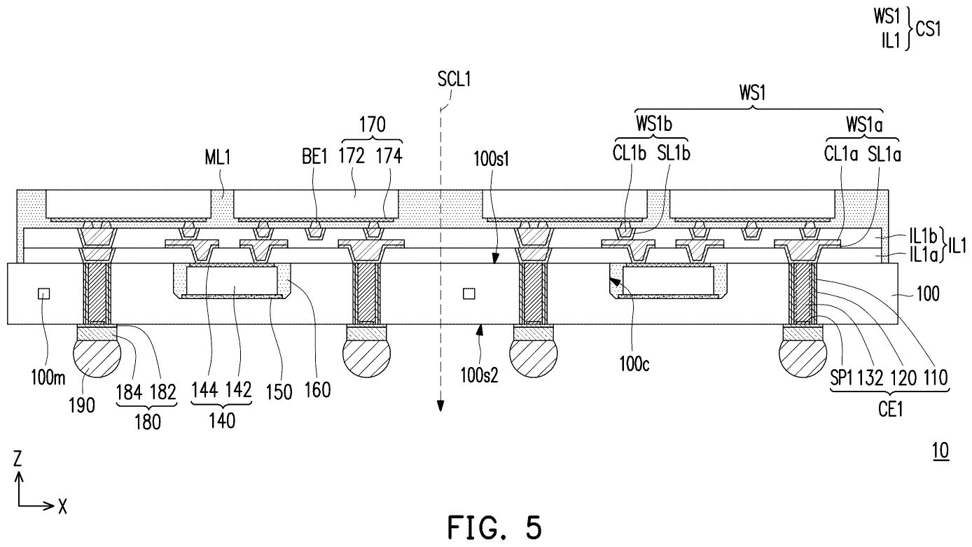

In this embodiment, the method for manufacturing the electronic device (for example, an electronic device 10 illustrated in FIG. 5) may include the following steps.

First, referring to FIG. 1, a substrate 100 is provided. In this embodiment, the substrate 100 includes a first surface 100s1 and a second surface 100s2 opposite to each other in a first direction (for example, a Z direction) and includes a cavity 100c extending from first surface 100s1 into the substrate 100 and a through hole 100 tv penetrating the first surface 100s1 and the second surface 100s2. In other words, sidewalls of the through hole 100tv connect the first surface 100s1 and the second surface 100s2 respectively. In this embodiment, the cavity 100c may be disposed between through holes 100tv. In some embodiments, the substrate 100 may include a mark 100m for alignment or tracking. For example, the mark 100m may be an alignment mark or a tracing mark. The substrate 100 may include polyimide, glass, silicon, or other suitable substrate materials. In some embodiments, the substrate 100 may be a glass substrate. In some embodiments, the substrate 100 may be a transparent substrate, with transmittance for white light that may be greater than or equal to 75%. In some embodiments, a thickness of the substrate 100 in the first direction (for example, the Z direction) may be in a range of 50 μm to 1000 μm. The coefficient of thermal expansion (CTE) of the substrate 100 may be in a range of 2 ppm/° C. to 10 ppm/° C. This design may buffer the warpage risk that may be caused when subsequent components are formed on the substrate 100. According to some embodiments, the first direction may be the normal direction of the substrate 100.

In some embodiments, at least one through hole 100tv is formed on the substrate 100. For example, laser process, etching process, drilling process, or combinations thereof may be performed on the first surface 100s1 and the second surface 100s2 of the substrate 100 that are opposite to each other in the first direction (for example, the Z direction), to form the through hole 100tv penetrating the substrate 100, or alternatively, laser drilling process may be performed from at least one surface of the substrate 100 to form the through hole 100tv penetrating the substrate 100, but the disclosure is not limited thereto. In other embodiments, modification treatment process (for example, laser modification process) and etching process may be performed on at least one surface of the substrate 100 to form the through hole 100tv in the substrate 100. In some embodiments, the etching process may include acid etching, alkaline etching, or combinations thereof. In some embodiments, the sidewalls of the through hole 100tv may have a first roughness, and the first surface 100s1 and the second surface 100s2 of the substrate 100 may respectively have a second roughness and a third roughness, where the first roughness may be smaller than the second roughness and third roughness. Through the above design, the skin effect of the electronic device 10 may be reduced, but the disclosure is not limited thereto.

Then, a conductive layer 110 and a conductive layer 120 are sequentially formed on the sidewalls of through hole 100tv. In some embodiments, the conductive layer 110 and the conductive layer 120 may be formed through the following steps. First, the conductive layer 110 may be formed through chemical vapor deposition (CVD), sputtering, atomic layer deposition (ALD), other suitable deposition methods, or processes of combinations thereof. Then, the conductive layer 110 may be used as seed layer and the seed layer may be grown through electroplating process to form the conductive layer 120, but the disclosure is not limited thereto. In other embodiments, the conductive layer 120 may be formed on the conductive layer 110, and the method of forming the conductive layer 120 may be similar to the conductive layer 110.

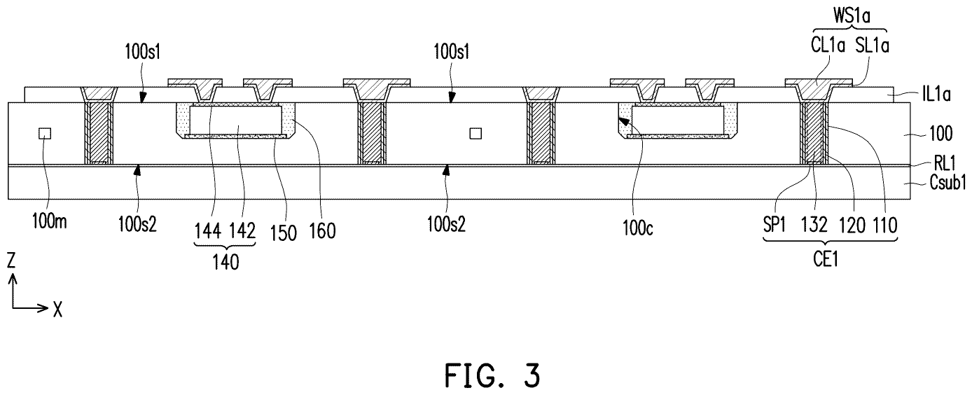

Then, a conductive element (a conductive element CE1 as shown in FIG. 3) is provided in the through hole 100tv, where the conductive element includes a seed layer pattern SP1 and a conductive pillar CP1 extending from the seed layer pattern SP1 along the first direction. That is, the conductive pillar CP1 is extending from the seed layer pattern SP1 in the direction (for example, in the Z direction) perpendicular to first surface 100s1 and second surface 100s2.

In this embodiment, the conductive element may be provided in the through hole 100tv through the steps shown as follows. First, a carrier substrate Csub1 is provided. The material of the carrier substrate Csub1 may include glass, quartz, sapphire, ceramic, stainless steel, silicon wafer, other suitable substrate materials, or combinations thereof, but the disclosure is not limited thereto. Then, a release layer RL1 and a seed layer (not shown) are sequentially provided on the carrier substrate Csub1. The method of forming the seed layer may be similar to the conductive layer. Then, patterning process is performed on the seed layer to form the seed layer pattern SP1. In this embodiment, the seed layer pattern SP1 may be formed to have a pattern corresponding to the position of the through hole 100tv of the substrate 100.

The release layer RL1 may be a temporary bonding layer, which may include adhesive thermal-type release material or optical-type release material, so that subsequently formed working units, elements, or film layers may be temporarily bonded on the release layer RL1. In other words, the release layer RL1 may assist the subsequently formed working units, elements, or film layers on the carrier substrate Csub1 to be removed from the carrier substrate Csub1. When thermal release material is used to form the release layer RL1, the thermal release material loses adhesiveness when heated, so that elements or film layers formed thereon may be peeled from the release layer RL1. For example, the release layer RL1 may be thermal release tape (TRT) or light-to-heat-conversion (LTHC) release coating. When optical release material is used to form the release layer RL1, the optical release material loses adhesiveness when exposed to radiation such as ultra-violet light (UV light), so that elements or film layers formed thereon may be peeled from the release layer RL1. The seed layer pattern SP1 may include any suitable conductive material, for example titanium (Ti), titanium nitride (TiN), tungsten (W), nickel (Ni), tantalum (Ta), copper, nitrides, carbides, other suitable metals, or alloys thereof, or combinations of the aforementioned materials.

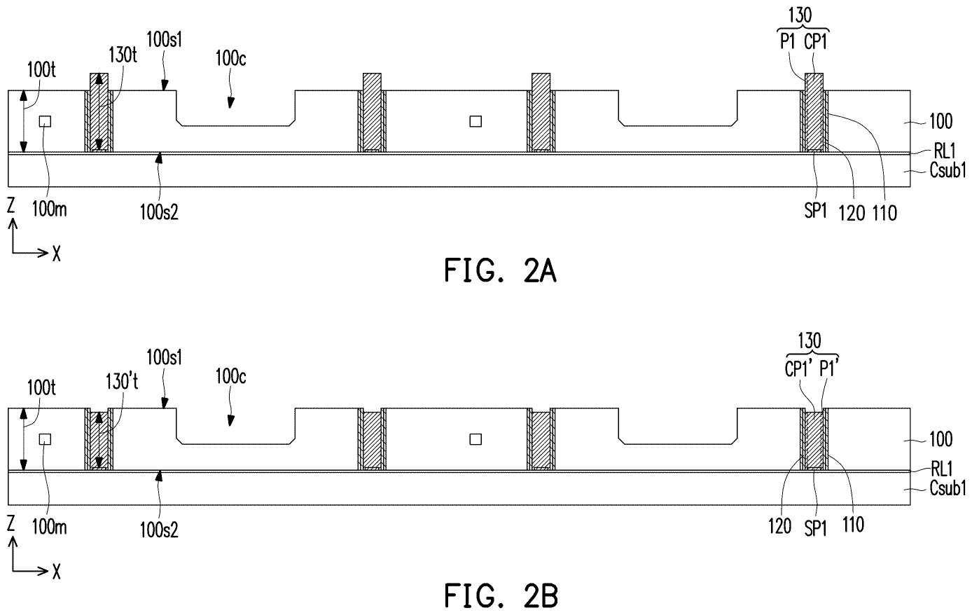

Then, the conductive pillar CP1 is formed on the seed layer pattern SP1. In some embodiments, the conductive pillar CP1 may be formed by growing the seed layer pattern SP1 through electroplating process to form the conductive pillar CP1, but the disclosure is not limited thereto. Then, the substrate 100 is bonded to the carrier substrate Csub1 in a manner of aligning the through hole 100tv with the conductive pillar CP1. Alternatively, the substrate 100 is bonded to the carrier substrate Csub1 after referring to the position of the alignment mark 100m. In this embodiment, the conductive layer 110 and the conductive layer 120 may be formed on the sidewalls of the through hole 100tv before bonding the substrate 100 to the carrier substrate Csub1, for example. Then, after bonding the substrate 100 to the carrier substrate Csub1 in the manner of aligning the through hole 100tv with the conductive pillar CP1, a first process is applied to the conductive layer 120 and/or the conductive pillar CP1, so that the conductive pillar CP1 and/or the conductive layer 120 diffuse toward each other and contact together to form a conductor 130 as illustrated in FIG. 2A. In some embodiments, the first process may also cause the seed layer pattern SP1 to grow laterally to form part of the conductor 130. In some embodiments, the first process may include heating process. In some embodiments, the heating process may be a heating process used in a hybrid bonding process, that is, a bonding surface between the conductor 130 and the conductive layer 120 may include metal-to-metal bonding surface.

Referring to FIG. 2A, the conductor 130 may be formed in the through hole 100tv of the substrate 100 and include the conductive pillar CP1 formed on the seed layer pattern SP1 and a diffusion part P1. In this embodiment, the diffusion part P1 may include a part diffusing from the seed layer pattern SP1 and the conductive pillar CP1 toward the conductive layer 120. In some embodiments, as shown in FIG. 2A, a thickness 130t of the conductor 130 may be greater than a thickness 100t of the substrate 100, but the disclosure is not limited thereto. In other embodiments, as shown in FIG. 2B, a thickness 130t′ of a conductor 130′ may be smaller than the thickness 100t of the substrate 100. The conductor 130′ may include a conductive pillar CP1′ and a diffusion part P1′. In this embodiment, a top surface of the conductive pillar CP1′ away from the seed layer pattern SP1 may be configured at a level lower than the first surface 100s1 of the substrate 100.

In the case where the thickness 130t of the conductor 130 is greater than the thickness 100t of the substrate 100, as shown in FIG. 2A, a planarization process such as chemical mechanical polishing (CMP) may be performed on the conductor 130 to remove a part of the conductor 130 on the first surface 100s1 of the substrate 100, thereby forming a conductor 132 as illustrated in FIG. 3, so that the conductive element CE1 formed in the through hole 100tv may include the seed layer pattern SP1, the conductor 132, the conductive layer 110, and the conductive layer 120. In this embodiment, a top surface of the conductor 132 away from the seed layer pattern SP1 may be configured at the same level as the first surface 100s1 of the substrate 100.

Then, referring to FIG. 3, a first electronic unit 140 is provided in the cavity 100c. In this embodiment, the first electronic unit 140 may include a foundation layer 142 and a circuit layer 144. The first electronic unit 140 may be known good die (KGD), diode, antenna unit, sensor, structure formed by semiconductor-related process, or component setting structure formed by semiconductor-related process on foundation layer. The foundation layer 142 may be film layer including substrate material such as polyimide, glass, silicon. The circuit layer 144 may include at least one insulation layer and at least one conductor and/or pad formed in the insulation layer. The insulation layer may include any suitable insulation material. The conductor and/or pad may include any suitable conductive material such as titanium (Ti), titanium nitride (TiN), tungsten (W), nickel (Ni), tantalum (Ta), nitride, carbide, other suitable metal, or alloy thereof, or combination of the aforementioned materials.

In this embodiment, the first electronic unit 140 may be attached to a bottom surface of the cavity 100c through an attachment member 150. A bottom filler 160 may fill in the cavity 100c to surround the first electronic unit 140. The attachment 150 may include any suitable adhesive material such as epoxy resin, die attach film (DAF), other suitable adhesive material, or combination of the aforementioned materials, but the disclosure is not limited thereto. In this embodiment, “one element surrounds another element” may refer to that the element may at least contact the side surface of the another element in cross-sectional view. For example, as shown in FIG. 3, the bottom filler 160 may contact the side surface of the first electronic unit 140.

In this embodiment, the foundation layer 142 may include a first side (for example, front side) on which or in which pads for transmitting signals are disposed and a second side (for example, back side) opposite to the first side in a first direction (for example, the Z direction), in which the circuit layer 144 is disposed at the first side of the foundation layer 142. In some embodiments, the pads for transmitting signals may be input/output pads (I/O pads).

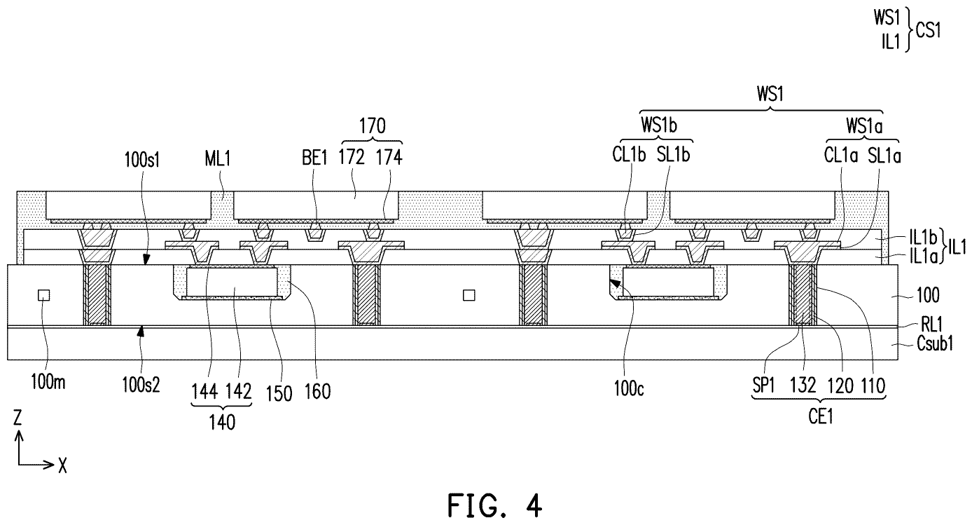

Then, a circuit structure (a circuit structure CS1 as shown in FIG. 4) is provided on the first surface 100s1 of the substrate 100, in which the circuit structure is electrically connected to the first electronic unit 140 and the conductive element CE1. In this embodiment, the circuit structure may be electrically connected to the circuit layer 144 of the first electronic unit 140.

In some embodiments, the circuit structure may be formed through the following steps. First, as shown in FIG. 3, an insulation layer IL1a is formed on the first surface 100s1 of the substrate 100. Then, openings exposing the conductive element CE1 and the circuit layer 144 are formed in the insulation layer IL1a. Subsequently, a seed layer SL1a is formed on the surface of the openings. Thereafter, a conductive layer CL1a is formed on the seed layer SL1a to form a wiring structure WS1a on the insulation layer IL1a. In this embodiment, electroplating process may be performed on the seed layer SL1a to grow the seed layer SL1a to form the conductive layer CL1a, but the disclosure is not limited thereto.

Then, referring to FIG. 3 and FIG. 4, an insulation layer IL1b and a wiring structure WS1b are formed on the insulation layer IL1a and the wiring structure WS1a to form the circuit structure CS1. The wiring structure WS1b may include a seed layer SL1b and a conductive layer CL1b formed on the seed layer SL1b. In this embodiment, electroplating process may be performed on the seed layer SL1b to grow the seed layer SL1b to the form conductive layer CL1b, but the disclosure is not limited thereto.

The insulation layer IL1a and the insulation layer IL1b may each include organic material or inorganic material. The organic material includes polyimide (PI), poly-p-xylylene (also called Parylene), benzocyclobutene (BCB), epoxy resin, polycarbonate (PC), polyethylene terephthalate (PET), polyethylene naphthalate (PEN), polymer, or other suitable organic materials, but the disclosure is not limited thereto. The inorganic material includes silicon oxide, silicon nitride, silicon oxynitride, or other suitable inorganic materials, but the disclosure is not limited thereto. The wiring structure WS1a and the wiring structure WS1b may each include any suitable conductive material, for example copper, titanium, nickel, combinations, or alloys of the aforementioned materials, but the disclosure is not limited thereto.

The circuit structure CS1 may include at least one insulation layer and at least one conductive layer to enable circuit redistribution and/or further enhance circuit fan-out area, or different electronic units may be electrically connected to each other through the circuit structure CS1. Alternatively, the circuit structure CS1 may be a substrate used as electrical interface wiring between one circuit and another circuit. The purpose of the circuit structure CS1 is to extend connections to wider pitch or redistribute connections to another connection with different pitch. In other words, the circuit structure CS1 in this document may also be a redistribution layer/structure. The circuit structure here or hereinafter may be electrically connected to each wafer or electronic unit through connection elements or other bonding elements. The steps of forming the circuit structure CS1 may include thermal process, deposition process, oxidation process, annealing process, surface treatment, or other processes.

In this embodiment, an insulation layer IL1 of the circuit structure CS1 may include the insulation layer IL1a and the insulation layer IL1b stacked in a first direction (for example, the Z direction), and a wiring structure WS1 of the circuit structure CS1 may include the wiring structure WS1a and the wiring structure WS1b stacked in the first direction (for example, the Z direction). The wiring structure WS1a and the wiring structure WS1b may each include a plurality of conductive patterns formed in the insulation layer IL1 and stacked along the Z direction and conductive vias connecting the conductive patterns.

Then, a second electronic unit 170 is provided on the circuit structure CS1. The second electronic unit 170 may be electrically connected to the circuit structure CS1. In some embodiments, the second electronic unit 170 may be connected to the first electronic unit 140 and the conductive element CE1 through the circuit structure CS1. In this embodiment, the second electronic unit 170 may be in plural and be spaced apart from each other in a second direction (for example, an X direction) different from the first direction (for example, the Z direction).

The second electronic unit 170 may include a chip, diode, antenna unit, memory unit, photonic integrated circuit (PIC) unit, sensor, or structure of semiconductor-related process. In this embodiment, the second electronic unit 170 may include a foundation layer 172 and a circuit layer 174. The circuit layer 174 may include at least one insulation layer and at least one conductor and/or pad formed in the insulation layer. The material required for the circuit layer 174 may be similar to the material of the circuit layer 144. In this embodiment, the foundation layer 172 may include a first side (for example, front side) on which or in which pads for transmitting signals are disposed and a second side (for example, back side) opposite to the first side in the first direction (for example, the Z direction), in which the circuit layer 174 is disposed at the first side of the foundation layer 172. In some embodiments, the pads for transmitting signals may be input/output pads. In this embodiment, the front side of the foundation layer 142 of the first electronic unit 140 may face the front side of the foundation layer 172 of the second electronic unit 170.

In this embodiment, the second electronic unit 170 may be electrically connected to the circuit structure CS1 through a bonding element BE1 disposed between the second electronic unit 170 and the circuit structure CS1. The material of the bonding element BE1 may be similar to conductor and/or pad.

Then, an encapsulation layer ML1 is formed on the substrate 100 to surround the circuit structure CS1 and the second electronic unit 170. The encapsulation layer ML1 may prevent the circuit structure CS1 and/or the second electronic unit 170 from being affected by external moisture, thereby improving the reliability of the electronic device. The encapsulation layer ML1 may include any suitable encapsulation material epoxy molding compound (EMC), but the disclosure is not limited thereto. In some embodiments, the encapsulation layer ML1 may be formed through the following steps. First, an encapsulation material layer covering the circuit structure CS1 and the second electronic unit 170 is formed on the substrate 100. Then, a planarization process such as chemical mechanical polishing (CMP) is performed on the encapsulation material layer to remove the encapsulation material layer above the second electronic unit 170, thereby forming the encapsulation layer ML1 that exposes the back side of the foundation layer 172 of the second electronic unit 170. In this embodiment, “one element surrounds another element” may refer to that the element may at least contact the side surface of the another element in cross-sectional view. For example, as shown in FIG. 4, the encapsulation layer ML1 may contact the side surfaces of the circuit structure CS1 and the second electronic unit 170.

Thereafter, referring to FIG. 4 and FIG. 5, after forming the encapsulation layer ML1, the release layer RL1 and the carrier Csub1 are removed by causing the release layer RL1 to lose adhesion. Then, a connection pad 180 and a connection element 190 formed on the connection pad 180 are formed on the second surface 100s2 of the substrate 100 to form the electronic device 10. In some embodiments, singulation process may be performed along scribe lines SCL1 to form multiple independent electronic elements.

In this embodiment, the connection pad 180 may include a seed layer 182 formed on the second surface 100s2 of the substrate 100 and a conductive layer 184 formed on the seed layer 182. In this embodiment, an electroplating process may be performed on the seed layer 182 to grow the seed layer 182 to form the conductive layer 184. The material of the connection pad 180 may be similar to conductor and/or pad. The connection element 190 may be a solder ball, but the disclosure is not limited thereto. The material of the connection element 190 may include tin silver (SnAg), tin, silver, nickel, gold, copper, conductive adhesive, or other suitable conductive material, but the disclosure is not limited thereto.

Hereinafter, the electronic device 10 of this embodiment will be illustrated by way of example through FIG. 5. The electronic device 10 may be formed through the manufacturing method as described above, but the disclosure is not limited thereto. Same or similar components are represented by same or similar reference symbols, so details will not be repeated here.

Referring to FIG. 5, the electronic device 10 includes the substrate 100, the first electronic unit 140, the conductive element CE1, and the circuit structure CS1. The substrate 100 may include the first surface 100s1 and the second surface 100s2 opposite to each other in the first direction (for example, the Z direction), in which the substrate 100 includes the cavity 100c and the through hole 100tv penetrating the first surface 100s1 and the second surface 100s2. The first electronic unit 140 may be disposed in the cavity 100c. The conductive element CE1 may be disposed in the through hole 100tv and electrically connected to the first electronic unit 140, in which the conductive element CE1 may include the seed layer pattern SP1 and the conductive pillar (that is, the conductor 132) extending from the seed layer pattern SP1 in a direction perpendicular to the first surface 100s1 and the second surface 100s2. The circuit structure CS1 may be disposed on the first surface 100s1 of the substrate 100 and electrically connect the first electronic unit 140 and the conductive element CE1.

In this embodiment, the conductive element CE1 may include a conductive layer (for example, the conductive layer 110 and/or the conductive layer 120) disposed on sidewalls of the through hole 100tv, in which the conductive layer and the seed layer pattern SP1 are spaced apart from each other in a direction (for example, in the X direction) parallel to the first surface 100s1 and the second surface 100s2.

In this embodiment, the electronic device 10 further includes the second electronic unit 170, the connection pad 180, and the connection element 190. The second electronic unit 170 may be disposed on the circuit structure CS1 and electrically connected to the first electronic unit 140 and the conductive element CE1 through the circuit structure CS1. The connection element 190 may be disposed on the second surface 100s2 of substrate 100 and electrically connected to the conductive element CE1. The connection pad 180 may be disposed between the conductive element CE1 and the connection element 190, in which the conductive element CE1 may be electrically connected to the connection element 190 through the connection pad 180, and the seed layer pattern SP1 may contact the connection pad 180.

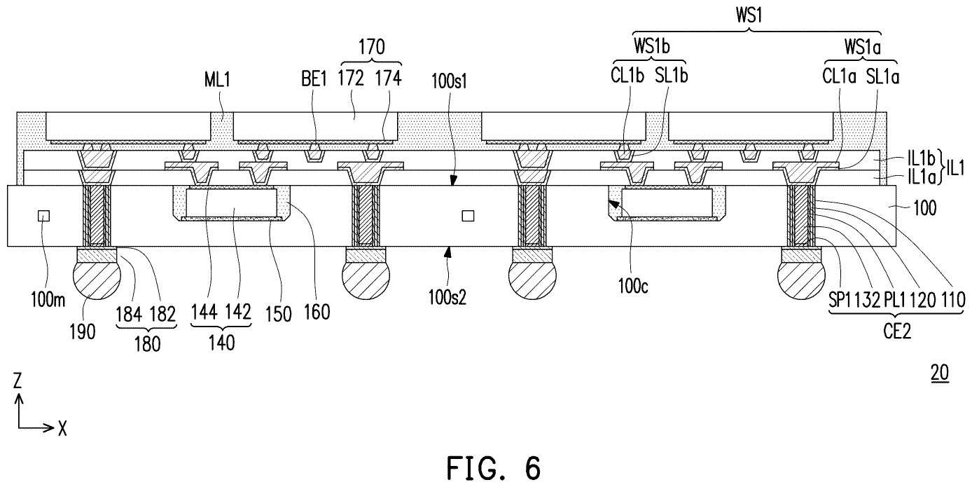

FIG. 6 is a schematic cross-sectional view of an electronic device according to another embodiment of the disclosure. An electronic device 20 shown in FIG. 6 is similar to the electronic device 10 shown in FIG. 1, and the main difference is that, a conductive element CE2 of the electronic device 20 is different from the conductive element CE1 of the electronic device 10. Other same or similar elements are represented by same or similar reference numerals, so details will not be repeated here.

Referring to FIG. 6, the conductive element CE2 of the electronic device 20 may include the seed layer pattern SP1, the conductor 132, the conductive layer 110, the conductive layer 120, and a promote layer PL1. In this embodiment, after forming the conductor 132, the promote layer PL1 may be filled between the conductive layer 120 and the conductor 132 (that is, the conductive pillar), which may fill the gap between the conductor 132 and the conductive layer 120 to help enhance reliability of the electronic device 20. In some embodiments, the promote layer PL1 may include heat dissipation material, which may help enhance heat dissipation efficiency of the electronic device 20. According to some embodiments, the promote layer PL1 may be a continuous or discontinuous film layer, and the promote layer PL1 may overlap the wiring structure WS1a, thereby stress may be buffered, but the disclosure is not limited thereto. The promote layer PL1 may include organic material such as polymer or epoxy resin. In some embodiments, the promote layer PL1 may include heat dissipation particles dispersed in organic material, and the heat dissipation particles may include graphene, metal particles, or any suitable heat dissipation material.

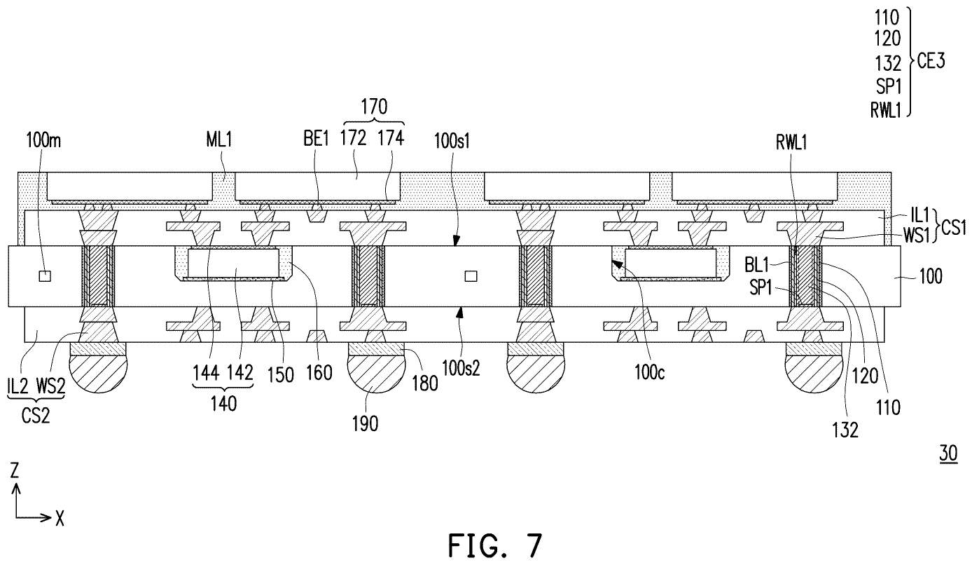

FIG. 7 is a schematic cross-sectional view of an electronic device according to yet another embodiment of the disclosure. An electronic device 30 shown in FIG. 7 is similar to the electronic device 10 shown in FIG. 1, and the main difference is that, a conductive element CE3 of the electronic device 30 is different from the conductive element CE1 of the electronic device 10, and the electronic device 30 further includes a buffer layer BL1 disposed between the conductive layer 110 and the substrate 100 and the circuit structure CS2 formed on the second surface 100s2 of the substrate 100. Other same or similar elements are represented by same or similar reference numerals, so details will not be repeated here.

Referring to FIG. 7, the buffer layer BL1 of the electronic device 30 may be disposed on sidewalls of the through hole 100tv (as shown in FIG. 1) and located between the conductive layer 110 and the substrate 100, which may help mitigate stress-induced cracking of the substrate 100, but the disclosure is not limited thereto. For example, the buffer layer BL1 may repair defects (such as micro cracks) generated when forming the through hole 100tv in the substrate 100 through the aforementioned modification treatment process (such as laser modification process) and etching process. In other embodiments, for example when the substrate 100 is a glass substrate, the buffer layer BL1 may mitigate differences in the coefficient of thermal expansion (CTE) between the substrate 100 and the conductive element CE3 subsequently formed in the through hole 100tv, to improve adhesion of the conductive element CE3 formed in the through hole 100tv or mitigate stress applied to the substrate 100. In this embodiment, the buffer layer BL1 is at least disposed on sidewalls of the through hole 100tv and extends to the first surface 100s1 and the second surface 100s2 of the substrate 100.

The buffer layer BL1 may include such as polyimide, polyparaxylene, benzocyclobutene, epoxy resin, polycarbonate, polyethylene terephthalate, polyethylene naphthalate, oxide, other suitable materials, or combinations thereof. That is, the buffer layer BL1 may include single layer or multilayer stack, and when the buffer layer BL1 is a multilayer stack, it may be an organic material stack, inorganic material stack, or organic material-inorganic material mixed stack. According to some embodiments, a toughness of the buffer layer BL1 may be greater than or equal to 0.1 kilojoules per square meter (kJ/m²) and less than or equal to 100 kJ/m² (that is, 0.1 kJ/m²≤the toughness of the buffer layer≤100 kJ/m²). In this document, the toughness of a film layer may be obtained by integrating the area under a stress-strain curve, and the stress-strain curve may be obtained by performing tensile testing on the film layer using a universal testing machine (UTM). A dissipation factor (DF) of the buffer layer BL1 may be less than the dissipation factor of the substrate 100. For example, the dissipation factor of the buffer layer BL1 may be less than 0.1 at operating frequencies greater than or equal to 10 megahertz, thereby reducing impact on signal transmission, particularly effectively reducing transmission impact on high-frequency signals.

In this embodiment, the circuit structure CS2 may be disposed on the second surface 100s2 of the substrate 100. The circuit structure CS2 may include the insulation layer IL2 formed on the substrate 100 and the wiring structure WS2 formed in the insulation layer IL2, where the wiring structure WS2 may be electrically connected to the conductive element CE3. The circuit structure CS2 may include at least one insulation layer and at least one conductive layer to enable circuit redistribution and/or further enhance circuit fan-out area, or different electronic units may be electrically connected to each other through the circuit structure CS2. Alternatively, the circuit structure CS2 may be a substrate used as electrical interface wiring between one circuit and another circuit. The purpose of the circuit structure CS2 is to extend connections to wider pitch or redistribute connections to another connection with different pitch. In other words, the circuit structure CS2 in this document may also be a redistribution layer/structure. The circuit structures herein or below may be electrically connected to each wafer or electronic unit through connection elements or other bonding elements. Steps for forming the circuit structure CS2 may include thermal process, deposition process, oxidation process, annealing process, surface treatment, or other processes. The insulation layer IL2 may include multiple insulation layers alternately stacked along the first direction (for example, the Z direction). The wiring structure WS2 may include multiple conductive patterns formed in the insulation layer IL2 and alternately stacked along the Z direction, and the conductive vias connecting the conductive patterns. The insulation layer IL2 may include insulation materials as listed for the insulation layer IL1, but the disclosure is not limited thereto. The wiring structure WS2 may include conductive materials as listed for the wiring structure WS1, but the disclosure is not limited thereto.

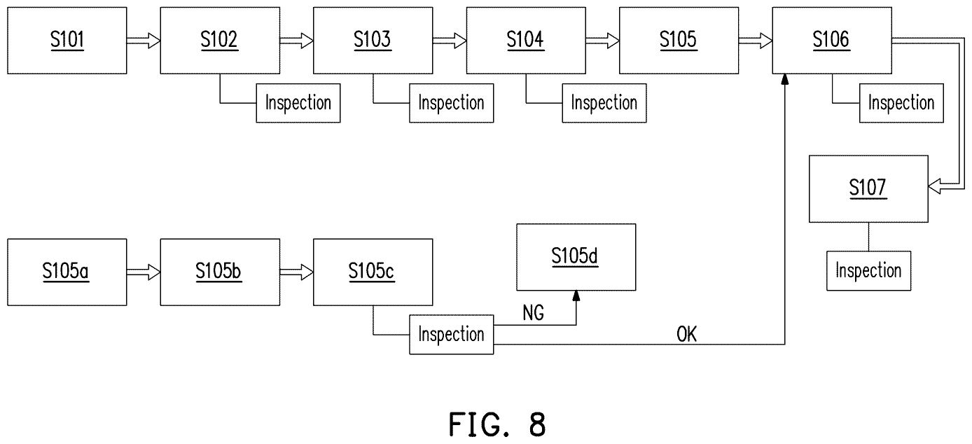

In this embodiment, the conductive element CE3 of the electronic device 30 may include the seed crystal pattern SP1, the conductor 132, the conductive layer 110, the conductive layer 120, and a rework layer RWL1. In this embodiment, the rework layer RWL1 may be disposed between the conductor 132 and the conductive layer 120. The material of the rework layer RWL1 may include conductive adhesive, tin, silver, or similar to conductor and/or connection pad. The rework layer RWL1 may be a film layer formed by performing rework process when the conductor 132 and the conductive layer 120 do not meet preset requirements after inspection (NG as illustrated in FIG. 8). In some embodiments, the rework process may include processes such as an inject process, chemical plating, or a reflow process.

FIG. 8 is a block diagram of a method for manufacturing an electronic device according to an embodiment of the disclosure.

Referring to FIG. 8, Step S101 may be a step of providing the substrate 100. Step S102 may be a step of performing modification treatment process on at least one surface of the substrate 100. Step S103 may be a process of executing etching process to form the through hole 100tv. Step S104 may be a step of forming the buffer layer BL1 on sidewalls of through hole 100tv. Step S105 may be a step of forming the conductive layer 110, the conductive layer 120, and the conductor 132. Step S106 may be a step of forming the circuit structure CS1. Step S107 may be a step of executing singulation process. In this embodiment, Step S105 may include Step 105a, Step 105b, Step 105c, and Step 105d. Step 105a may be a process of forming the conductive layer 110 and the conductive layer 120 on the sidewalls of through hole 100tv. Step 105b may be a process of forming the conductive pillar CP1 on the carrier substrate Csub1. Step 105c may be a step of executing the first process. Step 105d may be a step of executing the rework process on the conductive elements that do not meet preset requirements after inspection (NG as illustrated in FIG. 8). The rework layer RWL1 illustrated in FIG. 7 may be formed through the rework process of Step 105d, for example. In some embodiments, the rework process may include processes such as inject process, chemical plating, or reflow process. After executing Step 105c, if the conductive element meets the preset requirements after inspection (OK as illustrated in FIG. 8), then the operation proceeds to Step S106.

In this embodiment, after executing Step S102, Step S103, Step S104, Step S105c, Step S106, and Step S107, inspection steps may be performed to enable the formed electronic device to have good reliability.

In summary, in the electronic device and the method for manufacturing the same according to embodiments of the disclosure, the conductive element includes a seed layer pattern and a conductive pillar extending from the seed layer pattern in a direction perpendicular to the first surface and second surface of the substrate. That is, the conductive element is provided in the through hole of the substrate by assembly method, thus may reduce negative effects caused by the process of forming the conductive pillar on the substrate or on the first electronic unit disposed in the substrate, thereby improving the reliability of the electronic device.

The foregoing embodiments are merely used to illustrate the technical solutions of the disclosure, and the embodiments are not intended to limit the disclosure. Although the disclosure has been described in detail with reference to the foregoing embodiments, person skilled in the art should understand that, they may still modify the technical solutions described in the foregoing embodiments, or perform equivalent substitutions on part or all of the technical features thereof; and these modifications or substitutions do not cause the essence of the corresponding technical solutions to depart from the scope of the technical solutions of the embodiments of the disclosure, and features between embodiments may be arbitrarily mixed and matched for use as long as they do not violate the spirit of the disclosure or conflict with each other.

Although the embodiments of the disclosure and the advantages thereof have been disclosed as above, it should be understood that persons skilled in the art may make modifications, substitutions, and refinements without departing from the spirit and scope of the disclosure, and features between embodiments may be arbitrarily mixed and substituted with each other to form other new embodiments. Furthermore, the protection scope of the disclosure is not limited to the processes, machines, manufacturing, material compositions, devices, methods and steps in the specific embodiments described in the specification. Persons skilled in the art may understand from the disclosed content of the disclosure that existing or future developed processes, machines, manufacturing, material compositions, devices, methods and steps, as long as they may implement substantially the same functions or obtain substantially the same results in the embodiments described herein, may all be used according to the disclosure. Therefore, the protection scope of the disclosure includes the aforementioned processes, machines, manufacturing, material compositions, devices, methods and steps. In addition, each claim constitutes an individual embodiment, and the protection scope of the disclosure also includes combinations of various claims and embodiments. The protection scope of the disclosure shall be determined by the appended claims.

What is claimed is:

1. An electronic device, comprising:
a substrate comprising a first surface and a second surface opposite to each other in a first direction, wherein the substrate comprises a cavity and a through hole penetrating the first surface and the second surface;
a first electronic unit disposed in the cavity;
a conductive element disposed in the through hole and electrically connected to the first electronic unit, wherein the conductive element comprises a seed layer pattern and a conductive pillar extending from the seed layer pattern along the first direction; and
a first circuit structure disposed on the first surface of the substrate and electrically connected to the first electronic unit and the conductive element.

2. The electronic device as claimed in claim 1, further comprising:
a second electronic unit disposed on the first circuit structure and electrically connected to the first electronic unit and the conductive element through the first circuit structure;
a connection element disposed on the second surface of the substrate and electrically connected to the conductive element; and
a connection pad disposed between the conductive element and the connection element, wherein the conductive element is electrically connected to the connection element through the connection pad, and the seed layer pattern contacts the connection pad.

3. The electronic device as claimed in claim 1, wherein the conductive element comprises a conductive layer disposed on a sidewall of the through hole, wherein the conductive layer and the seed layer pattern are spaced apart from each other in a second direction parallel to the first surface and the second surface.

4. The electronic device as claimed in claim 3, further comprising:
a buffer layer disposed between the conductive layer and the substrate.

5. The electronic device as claimed in claim 4, wherein the buffer layer has a toughness greater than or equal to 0.1 kilojoules per square meter (kJ/m²) and less than or equal to 100 kilojoules per square meter (kJ/m²).

6. The electronic device as claimed in claim 5, wherein a dissipation factor of the buffer layer is less than 0.1.

7. The electronic device as claimed in claim 3, wherein the conductive element comprises a promote layer disposed between the conductive layer and the conductive pillar, wherein the promote layer comprises a heat dissipation material.

8. The electronic device as claimed in claim 7, wherein the first circuit structure comprises a first insulation layer and a first wiring structure in the first insulation layer and electrically connected to the first electronic unit and the conductive element, and the first wiring structure comprises a part overlapping the promote layer in the first direction.

9. The electronic device as claimed in claim 7, wherein the promote layer comprises a part disposed between the seed layer pattern and the conductive layer in the second direction.

10. The electronic device as claimed in claim 7, further comprising:
a second circuit structure disposed on the second surface of the substrate, wherein the conductive element electrically connects the second circuit structure to the first circuit structure,
wherein the second circuit structure comprises a second insulation layer and a second wiring structure in the second insulation layer and electrically connected to the conductive element, and the second wiring structure comprises a part overlapping the promote layer in the first direction.

11. The electronic device as claimed in claim 10, wherein the seed layer pattern comprises a top surface contacting the conductive pillar and a bottom surface contacting the part of the second wiring structure.

12. The electronic device as claimed in claim 1, wherein the through hole comprises a sidewall connecting the first surface and the second surface, and the seed layer pattern is spaced apart from the sidewall.

13. A method for manufacturing an electronic device, comprising:
providing a substrate, wherein the substrate comprises a first surface and a second surface opposite to each other in a first direction, and comprises a cavity extending from the first surface into the substrate and a through hole penetrating the first surface and the second surface;
providing a conductive element in the through hole, wherein the conductive element comprises a seed layer pattern and a conductive pillar extending from the seed layer pattern along the first direction;
providing a first electronic unit in the cavity; and
providing a first circuit structure on the first surface of the substrate, wherein the first circuit structure is electrically connected to the first electronic unit and the conductive element.

14. The method as claimed in claim 13, wherein providing the conductive element comprises the following steps:
providing a carrier;
forming the seed layer pattern on the carrier at positions corresponding to the through holes of the substrate;
forming the conductive pillar on the seed layer pattern; and
bonding the substrate to the carrier in a manner of aligning the through hole with the conductive pillar.

15. The method as claimed in claim 14, wherein providing the conductive element further comprises:
forming a conductive layer on a sidewall of the through hole before bonding the substrate to the carrier; and
after bonding the substrate to the carrier in the manner of aligning the through hole with the conductive pillar, applying a first process to the conductive pillar and/or the conductive layer, so that the conductive pillar and/or the conductive layer diffuse toward each other and contact together.

16. The method as claimed in claim 15, wherein the first process comprises a heating process used in a hybrid bonding process.

17. The method as claimed in claim 15, further comprising:
performing a rework process on the conductive element after executing the first process, to form a rework layer between the conductive layer and the conductive pillar.

18. The method as claimed in claim 17, wherein the rework process comprises an inject process, chemical plating, a reflow process, or a combination thereof.

19. The method as claimed in claim 15, further comprising:
before providing the first circuit structure on the first surface of the substrate, removing a part of the conductive pillar protruding from the first surface of the substrate through a planarization process.

20. The method as claimed in claim 15, further comprising:
forming a buffer layer between the conductive layer and the substrate on the sidewall of the through hole before bonding the substrate to the carrier.
